(19) United States
(12) Patent Application Publication
(10) Pub. No.: US 2007/0071255 A1
(43) Pub. Date: Mar. 29, 2007

(54) Adaptive Sound Reproduction

(75) Inventor: Daniel Willem Elisabeth Schobben, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/576,163

(22) PCT Filed: Oct. 6, 2004
(86) PCT No.: PCT/IB04/51982

§ 371 Date: Apr. 19, 2006

(30) Foreign Application Priority Data
Oct. 24, 2003 (EP) 03103941.5

(51) Int. Cl. H03G 5/00; H03G 9/00

(52) U.S. Cl. 381/98; 381/102

(57) ABSTRACT

To prevent distortion when sound is reproduced using a loudspeaker or similar transducer, the amplitude of the sound signal in a particular frequency range (I) may be reduced if it exceeds a threshold (L_{mAx I}). The invention proposes to wholly or partially map the amplitude reduced frequencies to other frequency ranges (II). As a result, the total sound level is not affected.

The present invention relates to adaptive sound reproduction. More in particular, the present invention relates to a device and a system for reproducing audio signals which adapt the audio signals to the audio transducers.

It is well known that audio transducers, such as loudspeakers, have frequency-dependent characteristics. While a particular transducer may reproduce one frequency or frequency range faithfully, reproducing another frequency range may introduce sound distortion. Smaller loudspeakers, for example, are typically more suitable for (re)producing higher frequencies, while larger loudspeakers are generally capable of producing low-frequency sound. At each frequency, a transducer typically has a maximum sound level which can be produced without introducing distortion. In the case of loudspeakers, for example, this maximum sound level is determined by the maximum excursion of the cone, any larger sound level will cause “clipping” of the sound signal, resulting in clearly audible sound distortion.

International patent application WO 01/03466 (Philips) discloses a loudspeaker protection system comprising filter means for defining one or more frequency ranges of an audio signal, controllable amplifier/attenuator means coupled to the filter means, and processing means coupled to control the amplifier/attenuator means. The system is capable of determining audio power in at least one of said frequency ranges representing relevant loudspeaker protection information used for selective audio power control in said at least one frequency range. The entire contents of WO 01/03466 are herewith incorporated in this document.

Although the system of WO 01/03466 is very effective in reducing or even substantially eliminating signal distortion in a particular frequency range, it has the disadvantage that some frequency ranges are attenuated, leading to an overall reduction of the sound volume.

It is an object of the present invention to overcome these and other problems of the Prior Art and to provide a method and a device which substantially eliminate signal distortion while substantially maintaining the output signal level.

Accordingly, the present invention provides a method of enhancing an audio signal, the method comprising the steps of:
selecting frequency ranges of the audio signal, each frequency range being capable of containing a respective signal having a signal level,
determining the signal level in a first frequency range, and
if the signal level in the first frequency range exceeds a threshold value:
   decreasing the signal level in the first frequency range, and
   increasing the signal level in a second frequency range different from the first frequency range.
      By determining the signal level in the first frequency range, comparing the detected signal level with a threshold level, and decreasing the signal level in the first frequency range if the signal level in the first frequency range exceeds the threshold value, signal distortion can be prevented. By then also increasing the signal level in a second frequency range, the second frequency range being different from the first frequency range, the decrease in the signal level in the first frequency range can be substantially compensated by an increase of the signal level in the second frequency range.

In a preferred embodiment, the second frequency range is higher than the first frequency range. That is, the second frequency range contains higher frequencies than the first frequency range. This is particularly advantageous for low frequencies as rendering these frequencies at an appreciable sound level typically requires large transducers which are not always available. However, the present invention is not limited to the second frequency range being higher than the first frequency range and embodiments can be envisaged in which the second frequency range contains lower frequencies than the first frequency range.

It is further preferred that the second frequency range is adjacent to the first frequency range. That is, a decrease in a frequency range preferably leads to an increase in the next (preferably higher) frequency range. Thus the nearest frequency range is used for sound level compensation, resulting in the smallest difference in frequency between the first and the second frequency range. Alternatively, or additionally, it is possible to increase the signal level in one or more other, non-adjacent second frequency ranges to compensate for a decrease in the first frequency range.

In a particularly advantageous embodiment, the step of increasing the signal level in the second frequency range comprises feeding part of the signal of the first frequency range to the second frequency range. In contrast to merely amplifying the second frequency range signal, this guarantees that a signal is present in the second frequency range and provides a direct link between the decrease in the first range and the increase in the second range.

Feeding part of the signal of the first frequency range to the second frequency range preferably comprises generating harmonics of the signal of the first frequency range. In this way, the signal fed from the first frequency range is frequency adjusted to the second frequency range. It is noted that if the second frequency range is lower than the first, sub-harmonics may advantageously be produced.

A further advantageous embodiment comprises the step of, if the signal level in the first frequency range exceeds a threshold value, increasing the signal level in a third frequency range different from the first and the second frequency range. If the signal level in both the first and the second frequency range exceeds a threshold value, the step of increasing the signal level in the second frequency range may be omitted.

It is preferred that the method of the present invention comprises the additional step of conditioning the audio signal prior to the step of selecting frequency ranges. This allows the audio signal to be adapted to the characteristics of the particular transducer and/or to the characteristics of the device used for enhancing the audio signal, for example by boosting a particular frequency range, such as bass frequencies.

The present invention further provides a device for enhancing an audio signal, the device comprising:
filter means for selecting frequency ranges of the audio signal, each selected frequency range being capable of containing a respective signal having a signal level,
detection means for determining the signal level in at least a first frequency range,
control means for generating control signals in response to the signal level determined by the detection means, and
signal amplification/attenuation means for amplifying or attenuating the signal of a respective frequency range,
   wherein the control means are arranged for:
determining whether the signal level in the first frequency range exceeds a respective threshold value and, if this is true,
decreasing the signal level in the first frequency range, and
increasing the signal level in a second frequency range different from the first frequency range.

By decreasing the signal level in the first frequency range, signal distortion can be avoided. By increasing the signal level in the second frequency range, the total sound output can remain substantially unaffected.

Although it is possible to simply increase the signal level in the second frequency range by sending an appropriate control signal to the respective signal amplification/attenuation means, it is preferred that the device of the present invention further comprises transfer means for transferring part of the signal of the first frequency range to the second frequency range. This allows outputting a signal in the second frequency range, even if no input signal were present in said range.

The transfer means preferably comprise a frequency shifting circuit. This allows the signal transferred from the first frequency range to the second frequency range to adapt a suitable frequency. To enable a controlled signal transfer from the first frequency range to the second frequency range it is preferred that the transfer means comprise a first signal multiplier for multiplying the signal from a first frequency range with a first coefficient before feeding said signal to the respective frequency shifting circuit. Similarly, it is preferred that the transfer means comprise a second signal multiplier for multiplying the frequency shifted signal from a first frequency range with a second coefficient before feeding said signal to the other frequency range. The control means are advantageously arranged for deriving the first coefficient and/or the second coefficient from the control signals.

The present invention additionally provides an audio system comprising a device as defined above.

The present invention will further be explained below with reference to exemplary embodiments illustrated in the accompanying drawings, in which:

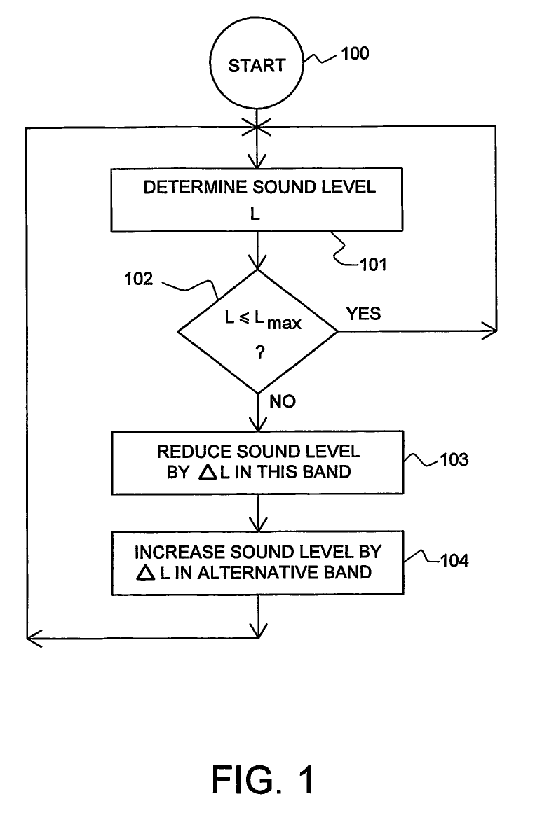

FIG. 1 schematically shows, in a flow diagram, a preferred embodiment of the method according to the present invention.

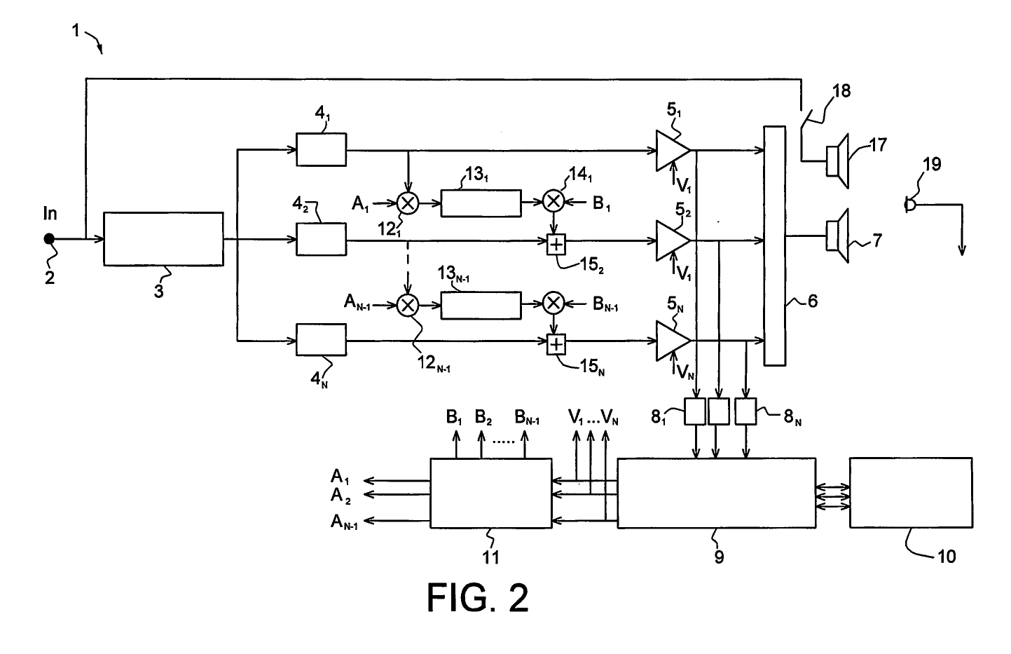

FIG. 2 shows a schematic diagram of a preferred embodiment of a sound adjustment circuit according to the present invention.

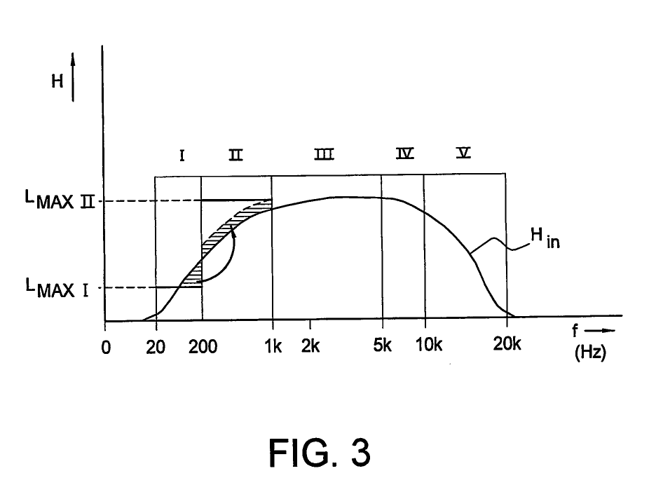

FIG. 3 schematically shows how the method and the device of the present invention affect an audio signal.

The method illustrated merely by way of non-limiting example in the flow diagram of FIG. 1 involves a number of steps which are carried out to monitor and, if necessary, adjust the sound level in a sound system in accordance with the present invention. The sound system may be a consumer sound system such as a so-called stereo set, an announcement system, a speech synthesizer system or any other suitable system producing sound.

The method of the present invention is preferably carried out for a number of frequency ranges, and preferably substantially in parallel. The diagram of FIG. 1 relates to one such frequency range and it will be understood that similar or identical diagrams can be drawn up for other frequency ranges.

After an initialization step 100, the method continues with step 101 in which the sound level L in the frequency range concerned is determined, for example by using a peak detector known per se. Then, in step 102, the sound level L is compared with a predetermined threshold sound level L_{MAX}. This threshold sound level L_{MAX} may be chosen so as to avoid any sound distortion, which may for example be caused by a loudspeaker cone reaching its maximum excursion.

If the detected sound level L is smaller than or equal to the threshold sound level L_{MAX} or expressed mathematically, if L≦L_{MAX} holds, the routine returns to step 101. If, however, the detected sound level L exceeds the threshold sound level L_{MAX}, or expressed mathematically, if L>L_{MAX} is true, then the routine continues with step 103 in which the sound level L in the (first) frequency range concerned is reduced by an amount ΔL. This amount ΔL may be equal to the difference between the sound level L and the threshold sound level L_{MAX}, written mathematically: ΔL=L−L_{MAX}. Alternatively, the amount ΔL may be equal to a predetermined amount.

The effect of step 103 is the reduction of the sound level L in the particular frequency range concerned. Although distortion may be avoided, the total sound level is also reduced. In accordance with the present invention, therefore, step 104 is carried out in which the sound level in another (second) frequency range is increased by the amount ΔL or a similar amount. As a result, the total sound output will remain substantially the same. More importantly, the present invention provides the possibility of compensating the sound level reduction in one frequency range by a sound level increase in an adjacent frequency range, thus minimizing the perceived effect of the sound adjustment. The alternative frequency range of step 104 is therefore preferably an adjacent frequency range.

After completing step 104, the routine returns to step 101 in which the sound level L is determined again. Monitoring and adjusting the sound level is preferably a continuous process.

In step 104 the sound level in an alternative frequency range is preferably increased by the same amount ΔL the sound level is decreased with in step 103, as mentioned above. However, this is not essential and embodiments can be envisaged in which the amounts of the increase in sound level are adjusted for the particular frequency range in which the increase is to be applied, for example in dependence on the characteristics of the transducers (typically loudspeakers) and/or on the subjective sound level as perceived by a user. The re-allocation or “mapping” of the excess sound level may thus take the properties of a particular frequency range into consideration.

As mentioned above, the amount ΔL the sound level is decreased with in step 103 is may be a predetermined amount. In this way, excessive adjustments may be avoided. As the routine returns to step 101 after step 104, the sound level may be reduced in an iterative manner, that is, in a number of steps. As the sound level L will change continuously, a continuous monitoring will generally be necessary. It is noted that the monitored sound level L may:
go up, in which case a (further) sound level reduction may be necessary,
be substantially constant during a certain time period, in which case further reductions are only necessary if a first reduction left the sound level exceeding the threshold, or
go down, in which case a further reduction will typically not be required, although this will of course depend on the actual sound level at a given moment.
   It is further noted that the threshold value L_{MAX} will depend on the particular frequency range and that different frequency ranges will typically have distinct threshold values.

The method of FIG. 1 is particularly effective for low audio frequency ranges, for example frequency ranges ranging from 20 to 100 Hz. Often transducers are not capable of producing sound in this frequency range at a high sound level without distortion. In accordance with the present invention, when the sound level in a 20 to 100 Hz frequency range is reduced to avoid distortion, the sound level in the next higher frequency range, for example ranging from 100 to 300 Hz, may be increased. In this way the total bass sound level as perceived by the user remains substantially the same, while eliminating signal distortion.

When decreasing the sound level in one frequency range it is preferred to increase the sound level in an adjacent frequency range, preferably but not necessarily the next higher frequency range. This may of course result in this adjacent frequency range also reaching its sound threshold value. In that case, the sound volume in the next frequency range may be increased as well. Thus the sound increase is allocated to the next available frequency range, that is, the next frequency range in which an increase is possible. If all frequency ranges have reached their threshold value, no sound increase is possible.

In some embodiments the sound level increase due to a reallocation of the sound levels may be limited to the next one or two frequency ranges to avoid any increase in the higher audio frequency ranges due to a low frequency range, and all subsequent frequency ranges, reaching their thresholds.

The alternative frequency range of step 104 in FIG. 1 may also be a special frequency or frequency range in which a particular transducer or group of transducers is particularly efficient. Thus one or more frequency ranges may be “mapped” onto a single frequency or frequency range. For example, a particular transducer may be very efficient at 120 Hz. Then any reduction in the sound levels of one or several frequency ranges due to reaching the threshold L_{MAX} will result to an increase in the sound level produced by the transducer at 120 Hz. Reference is made to European Patent Applications 03 103 398.8 [ID613750] and 03 103 396.2 [ID614271], the entire contents of which are herewith incorporated in this document.

The embodiment of a sound adjustment device 1 shown merely by way of non-limiting example in FIG. 2 comprises an input terminal 2 for receiving an audio input signal. A conditioning filter 3 is coupled to the input terminal 2 and conditions the received audio input signal, for example by attenuating higher frequencies so as to boost lower frequencies. The conditioning filter may be provided with a built-in amplifier but it is preferred to use a separate amplifier (not shown) for amplifying the audio signal before feeding it to the conditioning filter 3.

The conditioned audio input signal is then fed to an array of N band pass filters 4₁, 4₂, . . . 4_{N}, where N is an integer ranging between two and ten, although larger values of N are also possible. Each band pass filter 4ᵢ(i=1 . . . N) defines a frequency range. The band pass filtered audio signals are each fed to a respective controlled amplifier/attenuator 5ᵢ(i=1 . . . N) which may amplify or attenuate the signal as necessary to avoid signal distortion. The signal amplification or attenuation of each amplifier/attenuator 5ᵢ is controlled by a respective control signal Vᵢ. The amplified or attenuated signals are subsequently passed to a signal addition circuit 6 which adds the signals to form an output signal which is then fed to a transducer 7. Although in FIG. 2 only a single transducer (loudspeaker) is shown, it will be understood that two or more transducers, or sets of transducers, may be used.

The outputs of amplifiers/attenuators 5₁ . . . 5_{N} are each connected to a respective peak detector 8₁ . . . 8_{N} for detecting the peak (maximum) value of the signal. These detected peak values are passed to a microprocessor 9 and processed to form a set of control (amplification/attenuation) signals V₁ . . . V_{N} which are fed to the amplifiers/attenuators 5₁ . . . 5_{N} respectively. As explained in more detail in International Patent Application WO 01/03466 referred to above, the microprocessor 9 may compare the peak or maximum signal level values L produced by the peak detectors 8ᵢ(i=1 . . . N) with predetermined threshold values L_{MAX} stored in a memory device 10 associated with the microprocessor 9. The memory device 10 preferably comprises a look-up table containing the threshold values L_{MAX}. If a detected peak value is less than its threshold value, the attenuation is zero. However, if a detected peak value exceeds the corresponding stored threshold value, the microprocessor determines an appropriate control (attenuation) signal value Vᵢ and feeds it to the corresponding amplifier/attenuator 5ᵢ so as to reduce the peak level of the respective signal. In this way, distortion of the audio signal output by the loudspeaker(s) 7 is avoided.

However, it will be clear that distortion is avoided at the expense of the sound volume output by the speaker(s) 7. In accordance with the present invention, therefore, the device 1 is arranged for attempting to preserve the overall sound volume. To this end, the outputs of band pass filters 4₁ . . . 4_{N-1} are each coupled to a signal multiplier 12₁ . . . 12_{N-1} which multiplies the band pass filtered audio signal with a respective first coefficient A₁ . . . A_{N-1}. The resulting signals are fed to respective signal correction units 13₁ . . . 13_{N-1}, which will be explained later in more detail. Further signal multipliers 14₁ . . . 14_{N-1} multiply the output signal of each signal correction unit 13₁ . . . 13_{N-1} by a second coefficient B₁ . . . B_{N-1} to form a volume correction signal which is then added, in a signal addition circuit 15₂ . . . 15_{N}, to the output signal of the next band pass filter 4₂ . . . . 4_{N}.

This way, each frequency range (except the first, lowest one) may receive a signal contribution from the preceding, lower frequency range to increase its respective output volume so as to compensate for the reduction in the output volume of the preceding stage(s).

It is noted that in the embodiment shown, the first band pass filter 41 has the lowest pass band, defining the lowest frequency range, and that no signal addition circuit is present between the first band pass filter 41 and the first attenuator 51 as there is no lower frequency range to receive a signal contribution from.

The coefficients Aᵢ and Bᵢ (i=1 . . . N−1) which together determine the extent to which the signal of a frequency range is used as a volume correction signal in the next frequency range, are produced by a logic circuit 11 which receives the attenuation coefficients V₁ . . . V_{N} as its inputs. Alternatively, the coefficients Aᵢ and Bᵢ may be produced directly by the microprocessor 9.

The signal correction units 13₁ . . . 13_{N-1} may each contain a frequency shifting circuit as disclosed in United States Patent U.S. Pat. No. 6,134,330 (Philips), the entire disclosure of which is herewith incorporated in this document. Such an “ultra bass” circuit is capable of substituting an audio signal with its harmonics, thus effectively doubling, tripling or quadrupling its frequency. In this way, (part of) the audio signal of one frequency range may be transformed into another, higher frequency range. The “ultra bass” circuit of U.S. Pat. No. 6,134,330 may comprise a first filter, a harmonics generator and a second filter connected in series for selecting a frequency range, generating harmonics of that frequency range and selecting harmonics to be output. An amplifier may be arranged in parallel to the series circuit mentioned above. The amplifier serves to amplify the original signal.

As shown in FIG. 2, a reference transducer (loudspeaker) 17 may be connected to the input 2 via a switch 18 so as to provide a reference acoustic audio signal. Preferably, transducer 17 is a high-quality transducer or set of transducers capable of rendering a wide audio frequency range at high sound levels without any appreciable distortion. The output of transducers 7 and 17 may be compared to determine the impact of the device 1. In addition, a calibration microphone 19 connected to a suitable amplifier (not shown) may be provided for calibrating the device 1 and determining the values of the coefficients Vᵢ. The conditioning filter 3 is designed and/or tuned so as to minimize the difference between the output of transducer 17 (original audio signal) and the output of transducer 7 (audio signal as affected by the device 1). The “conditioning” of conditioning filter 3 therefore comprises an adaptation of the original audio signal to the transducer 7.

An exemplary set of frequency ranges is schematically shown in FIG. 3. An audio frequency range has frequencies from approximately 20 Hz to approximately 20 kHz. In the example shown, this frequency range is divided into five frequency ranges:

I. 20 Hz-200 Hz,

II. 200 Hz-1 kHz,

III. 1 kHz-5 kHz,

IV. 5 kHz-10 kHz

V. 10 kHz-20 kHz.

It will be understood that this is an example only and that both the number of frequency ranges and their boundary values may be chosen differently.

The frequency distribution Hᵢₙ of the input signal is shown to range from approximately 20 Hz to approximately 20 kHz. This frequency distribution reflects the average sound level L of the audio signal at various frequencies.

Suppose that the maximum sound level in the first frequency range I is L_{MAX I} as indicated in FIG. 3. This maximum sound level may be dictated by the properties of a transducer which introduces signal distortion if it is attempted to produce a higher sound level. As can be seen, the actual input sound level may exceed this maximum level L_{MAX I}. As discussed above, according to a first aspect of the present invention the sound level produced is limited to L_{MAX I}. However, this would effectively reduce the sound level in frequency range I and hence reduce the overall sound level. In accordance with a second aspect of the present invention, therefore, the difference ΔL in sound volume is “mapped” to another frequency range, in the example shown the next higher frequency range II, so as to keep the overall sound level substantially constant. The sound volume added to frequency range II is therefore preferably equal in magnitude to the reduction ΔL in the sound volume of frequency range II.

When increasing the sound volume in another frequency range, in the example shown adjacent frequency range II, it is of course checked whether the increased sound volume exceeds the threshold L_{MAX II} of frequency range II. In the example shown, this is not the case and the full sound volume increase ΔL can be made in frequency range II. If, however, this increase would raise the sound level in frequency range II above the maximum value L_{MAX II}, the increase in frequency range II will be limited so as to not exceed the threshold. In this case, part of the increase ΔL may be mapped to a further frequency range, for example frequency range III in FIG. 3.

It is also possible to initially transfer the sound volume increase to a non-adjacent frequency range, for example from frequency range I to frequency range III, skipping frequency range II. From a higher frequency range it is possible to transfer the sound volume increase to a lower frequency range, for example from V to IV or from V to III.

As mentioned above, one of the frequency ranges could be a special frequency range dedicated to a particular transducer which is very efficient in that particular range. Such a special frequency range can be very narrow, for example ranging only from approximately 115 Hz to approximately 125 Hz, being centered around the frequency (in the present example 120 Hz) at which a particular transducer has its maximum efficiency.

The present invention can advantageously be used in mini and micro audio sets, portable audio equipment, television sets, home cinema sound systems, computer equipment, and other devices.

The present invention is based upon the insight that most audio transducers can produce almost all audio frequencies without any substantial distortion at low sound pressure levels but that limiting the transducer output in a certain frequency range to prevent distortion reduces the overall sound pressure level output by the transducer. The present invention benefits from the further insight that the total sound pressure level output by a transducer or set of transducers may be substantially maintained, even if the output in one or more frequency ranges is reduced, by increasing the output in another frequency range or other frequency ranges.

It is noted that any terms used in this document should not be construed so as to limit the scope of the present invention. In particular, the words “comprise(s)” and “comprising” are not meant to exclude any elements not specifically stated. Single (circuit) elements may be substituted with multiple (circuit) elements or with their equivalents.

It will be understood by those skilled in the art that the present invention is not limited to the embodiments illustrated above and that many modifications and additions may be made without departing from the scope of the invention as defined in the appending claims.

1. A method of enhancing an audio signal, the method comprising the steps of:
selecting frequency ranges (I, II, . . . ) of the audio signal, each frequency range being capable of containing a respective signal having a signal level (L),
determining the signal level (L) in a first frequency range (I), and
if the signal level (L) in the first frequency range (I) exceeds a threshold value (L_{MAX I}):
decreasing the signal level in the first frequency range, and
increasing the signal level in a second frequency range (II) different from the first frequency range (I).

2. The method according to claim 1, wherein the second frequency range (II) is higher than the first frequency range (I).

3. The method according to claim 1, wherein the second frequency range (II) is adjacent to the first frequency range (I).

4. The method according to claim 1, wherein the step of increasing the signal level (L) in the second frequency range (II) comprises feeding part of the signal of the first frequency range (I) to the second frequency range (II).

5. The method according to claim 4, wherein feeding part of the signal of the first frequency range (I) to the second frequency range (II) comprises generating harmonics of the signal of the first frequency range.

6. The method according to claim 1, further comprising, if the signal level (L) in the first frequency range (I) exceeds a threshold value (L_{MAX I}), increasing the signal level in a third frequency range (III) different from the first and the second frequency range.

7. The method according to claim 1, wherein, if the signal level in both the first (I) and the second frequency range (II) exceeds a respective threshold value (L_{MAX I}, L_{MAX II}), the step of increasing the signal level in the second frequency range is omitted.

8. The method according to claim 1, further comprising the step of conditioning the audio signal prior to the step of selecting frequency ranges.

9. A device (1) for enhancing an audio signal, the device comprising:
filter means (4₁-4_{N}) for selecting frequency ranges (I, II, . . . ) of the audio signal, each selected frequency range being capable of containing a respective signal having a signal level (L),
detection means (8₁-8_{N}) for determining the signal level (L) in at least a first frequency range (I),
control means (9, 10) for generating control signals (V₁-V_{N}) in response to the signal level determined by the detection means, and
signal amplification/attenuation means (5₁ . . . 5_{N}) for attenuating the signal of a respective frequency range in response to the said control signals (V₁-V_{N}),
wherein the control means (9, 10) are arranged for:
determining whether the signal level (L) in the first frequency range (I) exceeds a respective threshold value (L_{MAX I}) and, if this is true,
decreasing the signal level (L) in the first frequency range (I), and
increasing the signal level in a second frequency range (II) different from the first frequency range.

10. The device according to claim 9, further comprising transfer means (12₁ . . . 12_{N-1}, 13₁ . . . 13_{N-1}, 14₁ . . . 14_{N-1}, 15₂ . . . 15_{N}) for transferring part of the signal of the first frequency range (e.g. I) to the second frequency range (e.g. II).

11. The device according to claim 10, wherein the transfer means comprise a frequency shifting circuit (13₁ . . . 13_{N-1}).

12. The device according to claim 11, wherein the transfer means comprise a first signal multiplier for multiplying the signal from the first frequency range with a first coefficient (A₁ . . . A_{N-1}) before feeding said signal to the respective frequency shifting circuit (13₁ . . . 13_{N-1}).

13. The device according to claim 11, wherein the transfer means comprise a second signal multiplier for multiplying the frequency shifted signal from the first frequency range with a second coefficient (B₁ . . . B_{N-1}) before feeding said signal to the second frequency range.

14. The device according to claim 12, wherein the control means (9, 10) are arranged for deriving the first coefficient (A₁ . . . A_{N-1}) and/or the second coefficient (B₁ . . . B_{N-1}) from the control signals (V₁-V_{N}).

15. The device according to claim 9, further comprising a conditioning filter (3) for conditioning the audio signal prior to selecting frequency ranges.

16. An audio system comprising a device (1) according to claim 9.
